(19) United States
(12) Patent Application Publication
(10) Pub. No.: US 2024/0313000 A1
(43) Pub. Date: Sep. 19, 2024

(54) INTERCONNECTS AT BACK SIDE OF SEMICONDUCTOR DEVICE FOR SIGNAL ROUTING

(71) Applicant: SAMSUNG ELECTRONICS CO., LTD., Suwon-si (KR)

(72) Inventors: Jintae KIM, Clifton Park, NY (US); Panjae PARK, Halfmoon, NY (US); Kang-ill SEO, Springfield, VA (US)

(73) Assignee: SAMSUNG ELECTRONICS CO., LTD., Suwon-si (KR)

(21) Appl. No.: 18/226,328

(22) Filed: Jul. 26, 2023

Related U.S. Application Data
(60) Provisional application No. 63/452,894, filed on Mar. 17, 2023.

(51) Int. Cl. H01L 27/12

(52) U.S. Cl. CPC H01L 27/124

(57) ABSTRACT

Provided is a semiconductor device including a 1^{st} frontside metal line at a front side of the semiconductor device; and a 1^{st} backside metal line at a back side of the semiconductor device, wherein the 1^{st} backside metal line is connected to the 1^{st} frontside metal line.

### CROSS-REFERENCE TO RELATED APPLICATION

This application is based on and claims priority from U.S. Provisional Application No. 63/452,894 filed on Mar. 17, 2023 in the U.S. Patent and Trademark Office, the disclosure of which is incorporated herein in its entirety by reference.

### BACKGROUND

### 1. Field

Apparatuses consistent with example embodiments of the disclosure relate to a semiconductor device including backside metal line structures provided at a back side of a semiconductor device.

### 2. Description of Related Art

Growing demand for an integrated circuit having a high device density and performance has introduced a backside power distribution network (BSPDN) formed at a back side of a semiconductor device based on a standard cell architecture which may include one or more transistors. The BSPDN provides a plurality of backside power rails (or buried power rails) in a substrate or a backside isolation structure formed at the back side of the semiconductor device so that source/drain regions of a transistor or a passive device terminal may be powered by the power rails from the buried power rails.

However, a high-density cell architecture for a semiconductor device such as a flip-flop circuit still has a plurality of metal lines (or interconnects) at a front side of the semiconductor device, and thus, there still remains problems of excessive connection resistance and capacitance as well as manufacturing complexity in implementing the high-density cell architecture using the frontside metal lines. Herein, the standard cell may also be referred to as cell or semiconductor cell, which includes a plurality of active regions and gate structures forming one or more of passive devices and transistors configured to perform a logic function such as AND, OR, NOR, NAND, XOR, multiplexer, etc.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

Various example embodiments provide a semiconductor device including at least one frontside metal line and at least one backside metal line for signal routing.

According to embodiments, there is provided a semiconductor device which may include: an input metal line at a front side of the semiconductor device; and at least one 1^{st} output metal line at a back side of the semiconductor device, wherein the input metal line is configured to receive an input signal of a 1^{st} logic circuit, and the 1^{st} output metal line is configured to output an output signal of the 1^{st} logic circuit, which may include a 1^{st} inverter circuit including a p-type field-effect transistor (FET) and an n-type FET.

According to embodiments, the semiconductor device may further include: an input contact structure or via at the back side of the semiconductor device; and at least one 2_{nd} output metal line at the front side of the semiconductor device, wherein the input contact structure or via is configured to receive the output signal of the 1^{st} logic circuit as an input signal of a 2^{nd} logic circuit, and the 2^{nd} output metal line is configured to output an output signal of the 2^{nd} logic circuit, which may include a 2^{nd} inverter including a 2^{nd} p-type FET and a 2^{nd} n-type FET.

According to embodiments, there is provided a semiconductor device which may include: a 1^{st} frontside metal line at a front side of the semiconductor device; and a 1^{st} backside metal line at a back side of the semiconductor device, wherein the 1^{st} backside metal line is connected to the 1^{st} frontside metal line. The semiconductor device may further include: a 1^{st} front-end-of-line (FEOL) structure comprising at least one of a 1^{st} source/drain region and a 1^{st} gate structure, and connected to the 1^{st} frontside metal line and the 1^{st} backside metal line.

According to embodiments, the semiconductor device may further include: a 2^{nd} frontside metal line at the front side of the semiconductor device; and a 2^{nd} backside metal line at the back side of the semiconductor device. The 1^{st} and 2^{nd} frontside metal lines may be connected to each other, and the 1^{st} and 2^{nd} backside metal lines may be connected to each other.

According to embodiments, there is provided a semiconductor device which may include: a 1^{st} FEOL structure comprising at least one of a 1^{st} source/drain region and a 1^{st} gate structure; a 1^{st} frontside metal line; and a 1^{st} backside metal line, wherein the 1^{st} FEOL structure is configured to be selectively connected to one of the 1^{st} frontside metal line and the 1^{st} backside metal line.

According to an embodiment, the semiconductor device may further include: a 2^{nd} FEOL structure including at least one of a 2^{nd} source/drain region and a 2^{nd} gate structure; a 2^{nd} frontside metal line; and a 2^{nd} backside metal line, wherein the 2^{nd} FEOL structure is selectively connected to the 2^{nd} frontside metal line or a 2^{nd} backside metal line.

According to embodiments, the 1^{st} and 2^{nd} frontside metal lines may be connected to each other, or the 1^{st} and 2^{nd} backside metal lines may be connected to each other.

### BRIEF DESCRIPTION OF DRAWINGS

Example embodiments of the disclosure will be more clearly understood from the following detailed description taken in conjunction with the accompanying drawings in which:

FIG. 1A is a top plan view of a cell architecture for a buffer circuit in which a plurality of frontside metal lines are formed according to a related art;

FIG. 1B is a top plan view of a cell architecture for a buffer circuit in which a plurality of frontside metal lines and backside metal lines are formed, according to an embodiment;

FIG. 1C illustrates a schematic of a buffer circuit;

FIG. 2A is a cross-section view of a cell architecture for a latch portion of a flip-flop circuit in which a plurality of frontside metal lines and a BSPDN including a plurality of buried power rails are respectively formed above and below 3DSFETs, according to an embodiment;

FIG. 2B is a cross-section view of a cell architecture for a latch portion of a flip-flop circuit in which a plurality of frontside metal lines and a BSPDN including a plurality of backside power rails and backside metal lines are respectively formed above and below 3DSFETs, according to an embodiment;

FIG. 2C is a cross-section view of a cell architecture for a latch portion of a flip-flop circuit in which a plurality of frontside metal lines and a BSPDN including a plurality of backside power rails and backside metal lines are respectively formed above and below 3DSFETs, according to another embodiment;

FIG. 2D is a schematic of a latch portion of a flip-flop circuit; and

FIG. 3 is a schematic block diagram illustrating an electronic device including a semiconductor device formed based on a cell architecture shown in FIG. 1B or 2B, according to an example embodiment.

### DETAILED DESCRIPTION OF EMBODIMENTS

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, nanosheet sacrificial layers, sacrificial isolation layers and channel isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, elements described as “below” or “beneath” other elements would then be oriented “above” the other elements. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd},” “3^{rd},” “4^{th},” “5^{th},” “6^{th}” etc. may be used herein to describe various elements, these elements should not be limited by these terms. These terms are only used to distinguish one element from another element. Thus, a 1^{st} element discussed below could be termed a 2^{nd} element without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” is used to compare a dimension of two or more elements, the term may cover a “substantially same” dimension.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments.

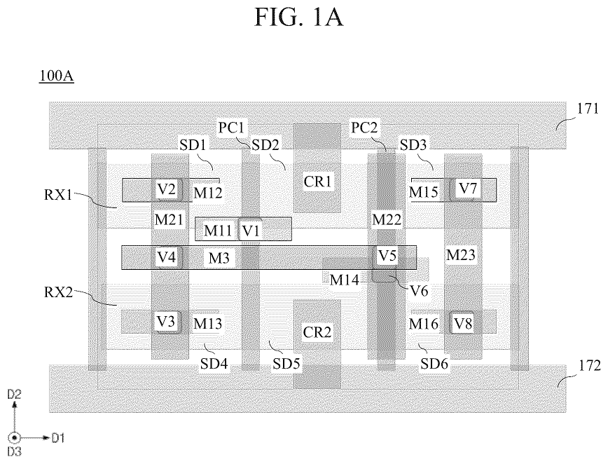

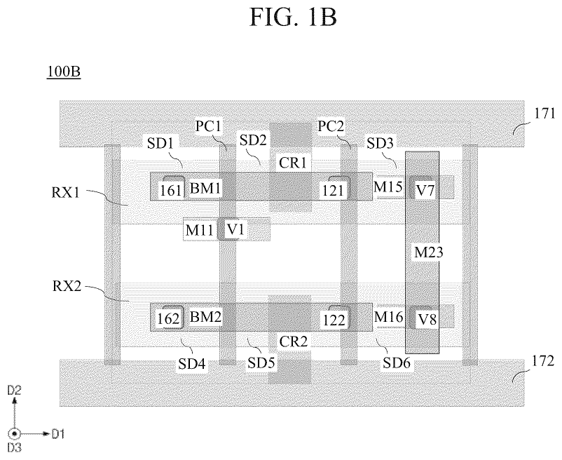

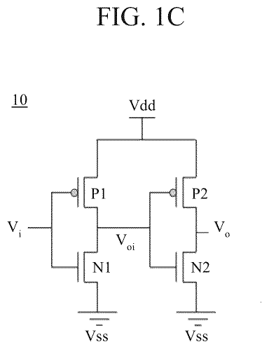

FIG. 1A is a top plan view of a cell architecture for a buffer circuit in which a plurality of frontside metal lines are formed according to a related art, and FIG. 1B is a top plan view of a cell architecture for the buffer circuit in which a plurality of frontside metal lines and backside metal lines are formed according to an embodiment. FIG. 1C illustrates a schematic of the buffer circuit.

The cell architectures described herein may be a basis of forming a semiconductor device. Thus, the cell architecture may include the same structural elements of the semiconductor device, and a front side and a back side of the cell architecture described herein may indicate a front side and a back side of the semiconductor device formed based on the cell architecture.

Referring to FIG. 1C, a buffer circuit 10 may be formed by two inverter circuits connected to each other in parallel between a 1^{st} voltage source (e.g., Vdd) and a 2^{nd} voltage source (e.g., Vss) providing a lower voltage than the 1^{st} voltage source. The two inverter circuits may be formed by an input complimentary metal-oxide-semiconductor (CMOS) device and an output CMOS device which receives an output signal of the input CMOS device as an input signal of the output CMOS device. The input CMOS device may be formed by a 1^{st} p-type metal-oxide-semiconductor field-effect transistor (PMOS) P1 and a 1^{st} n-type metal-oxide-semiconductor field-effect transistor (NMOS) N1 serially connected to each other between the two voltage sources. The output CMOS device may be formed by a 2^{nd} PMOS P2 and a 2^{nd} NMOS N2 which are also serially connected to each other between the two voltage sources.

Referring to FIG. 1A, a cell architecture 100A, in which the buffer circuit 10 of FIG. 1C is implemented by a single cell, may include two active regions RX1 and RX2 extended in a D1 direction and arranged in a D2 direction, and a plurality of gate structures including a 1^{st} gate structure PC1 and a 2^{nd} gate structure PC2 extended in the D2 direction and arranged in the D1 direction across the active regions RX1 and RX2.

The active regions RX1 and RX2 may be provided for formation of source/drain regions and channel structures of the two CMOS devices thereon. Each of the CMOS devices formed in the cell architecture 100A may be a FinFET or a nanosheet transistor, not being limited thereto. The gate structures PC1 and PC2 may be provided for formation of gate electrodes thereon. The active regions RX1, RX2, the gate structures PC1, PC2 and the channel structures surrounded by the gate structures PC1, PC2 may be referred to as front-end-of-line (FEOL) structures of the cell architecture 100A and a semiconductor device formed based on the cell architecture 100A.

The cell architecture 100A may include a plurality of interconnects, also referred to as back-end-of-line (BEOL) structures, formed at a front side of the cell architecture to implement the buffer circuit 10 shown in FIG. 1C. The interconnects may include six 1^{st} frontside metal lines M11-M16 formed at a 1^{st} metal layer, three 2^{nd} frontside metal lines M21-M23 formed at a 2^{nd} metal layer above the 1^{st} metal layer, and on 3^{rd} frontside metal line M3 formed at a 3^{rd} metal layer above the 2^{nd} metal layer. The interconnects may also include a plurality of vias V1-V8 connecting the frontside metal lines M11-M16, M21-M23 and M3 to each other or the FEOL structures. However, some via structures are omitted in FIG. 1B for brevity purposes when descriptions thereof are not necessary to explain the embodiments. For similar reasons, some contact structures connecting the FEOL structures to the vias V1-V8 or the 1^{st} frontside metal lines M11-M16 are omitted in FIG. 1A along with descriptions thereof.

Further, the cell architecture 100A may include a 1^{st} power rail 171 and a 2^{nd} power rail 172 extended in the D1 direction at upper and lower boundaries of the cell architecture 100A, respectively, in parallel with the 1^{st} frontside metal lines M11-M16. The power rails 171 and 172 may be formed at the same 1^{st} metal layer where the 1^{st} frontside metal lines M11-M16 are formed. The power rails 171 and 172 may be connected to source/drain regions formed in the active regions RX1 and RX2 through contact structures CR1 and CR2, respectively.

The active region RX1 may include three source/drain regions SD1, SD2 and SD3 which may be doped with p-type impurities such as boron (B), gallium (Ga) and/or indium (In), and the active region RX2 may also include three source/drain regions SD4, SD5 and SD6 which may be doped with n-type impurities such as phosphorus (P), arsenic (As) and/or antimony (Sb).

Referring to FIGS. 1A and 1C, the source/drain regions SD1 and SD2 may be connected to each other through a channel structure formed below the gate structure PC1, thereby forming the PMOS1, and the source/drain regions SD2 and SD3 may be connected to each other through a channel structure formed below the gate structure PC2, thereby forming the 2^{nd} PMOS P2. The source/drain region SD2 may be a common source/drain region of the two PMOSs P1 and P2 connected to the 1^{st} voltage source through the 1^{st} power rail 171. That is, the source/drain region SD2 may implement a source terminal of the 1^{st} PMOS P1 as well as a source terminal of the 2^{nd} PMOS P2 of the buffer circuit 10 shown in FIG. 1C.

Similarly, the source/drain regions SD4 and SD5 may be connected to each other through a channel structure formed below the gate structure PC2, thereby forming the NMOS1, and the source/drain regions SD2 and SD3 may be connected to each other through a channel structure formed below the gate structure PC3, thereby forming the 2^{nd} NMOS N2. The source/drain region SD5 may be also be a common source/drain region of the two NMOSs N1 and N2 connected to a 2^{nd} voltage source (e.g., Vss) through the 2^{nd} power rail 172. That is, the source/drain region SD5 may implement a source terminal of the 1^{st} NMOS N1 as well as a source terminal of the 2^{nd} NMOS N2 of the buffer circuit 10 shown in FIG. 1C.

The 1^{st} frontside metal line M11 may be connected to the 1^{st} gate structure PC1 through the via V1 therebelow to provide a common input signal Vito the input CMOS device. The 1^{st} frontside metal lines M12 and M13 may be connected to the source/drain regions SD1 and SD4 though one or more contact structures and/or vias, respectively. These 1^{st} frontside metal lines M12 and M13 may be connected to the 2^{nd} frontside metal line M21 through the vias V2 and V3 thereabove, respectively, thereby being connected to each other. Here, the source/drain regions SD1 and SD4 may be drain terminals of the 1^{st} PMOS P1 and the 1^{st} NMOS N1 connected to each other to output a output signal Vₒᵢ of the input CMOS device through the via V4 and the 3^{rd} frontside metal line M3. The via V4 connects the 2^{nd} frontside metal line M21 therebelow to the 3^{rd} frontside metal line M3 thereabove.

The output signal Vₒᵢ may be input to the output CMOS device as an input signal of the output CMOS device, which is formed of the 2^{nd} PMOS P2 and the 2^{nd} NMOS N2, through the 3^{rd} frontside metal line M3, the via V5 therebelow, the 2^{nd} frontside metal line M22 therebelow, the via V6 therebelow, and the 1^{st} frontside metal line M14. Thus, the output signal Vₒᵢ may be input as a common input signal to the 2^{nd} gate structure PC2 of the output CMOS device.

Based on the common input signal, the source/drain region SD3 of the 2^{nd} PMOS P2 and the source/drain region SD6 of the 2^{nd} NMOS N2 may output respective output signals to the 1^{st} frontside metal lines M15 and M16 through one or more contact structures and/or vias, respectively. These 1^{st} frontside metal lines M15 and M16 may be connected to the 2^{nd} frontside metal line M23 through the vias V7 and V8 thereabove, respectively, thereby to output to the 2^{nd} frontside metal line M23 the respective output signals as an output signal Vₒ of the output CMOS device, as shown in FIG. 1C.

Thus, the cell architecture 100A shown in FIG. 1A according to the related art may implement the buffer circuit 10 shown in FIG. 1C using at least ten frontside metal lines as interconnects, which may increase signal routing traffic and connection resistance and capacitance at the front side of a semiconductor device formed based on the cell architecture 100A. However, a cell architecture 100B shown in FIG. 1B may implement the buffer circuit 10 using a smaller number of frontside metal lines to address the heavy signal routing traffic and connection resistance and capacitance at the front side of the semiconductor device formed based on the cell architecture 100A.

Referring to FIG. 1B, the cell architecture 100B may have the same two active regions RX1 and RX2, source/drain regions SD1-SD6 and gate structures PC1 and PC2 as those included in the cell architecture 100A of FIG. 1A to implement the buffer circuit 10 shown in FIG. 1C. The cell architecture 100B may also have the same 1^{st} frontside metal lines M11, M15 and M16, the via V1, the 2^{nd} frontside metal line M23, and the vias V7 and V8 as those included in the cell architecture 100A of FIG. 1A. However, the 1^{st} frontside metal lines M12, M13, M14, the 2^{nd} metal lines M21, M22 and the 3^{rd} metal line M3 are replaced by backside metal lines in the cell architecture 100B. Thus, duplicate descriptions may be omitted and only different aspects of the cell architecture 100B may be described herebelow.

As interconnects, the cell architecture 100B may include three 1^{st} frontside metal lines M11, M15 and M16 at a 1^{st} metal layer, one 2^{nd} frontside metal line M23 at a 2^{nd} metal layer above the 1^{st} metal layer, and two backside metal lines BM1 and BM2 at a back side of the cell architecture 100B. The 1^{st} frontside metal lines M11, M15 and M16, and the 2^{nd} frontside metal line M23 may be the same as those included in the cell architecture 100A as shown in FIG. 1A. However, the 1^{st} frontside metal lines M12-M14, the 2^{nd} frontside metal line M21, M22 and the 3^{rd} backside metal line M31 in the cell architecture 100A may be replaced by the backside metal lines BM1 and BM2 in the cell architecture 100B. Thus, the cell architecture 100B may implement the buffer circuit with a less number of metal lines and a less complexity at a front side.

The backside metal lines BM1 and BM2 may be formed in a substrate of the PMOSs P1-P2 and the NMOSs N1-N2 or a backside isolation structure which may have replaced the substrate for the formation the backside metal lines BM1 and BM2 therein. The backside metal lines BM1 and BM2 may be connected to the 1^{st} and 4^{th} source/drain regions SD1 and SD4 through backside contact structures 161 and 162, respectively, in the substrate or the backside isolation structure. There may be a backside via between the backside contact structure 161 and the 1^{st} source/drain region SD1 and between the backside contact structure 162 and the 4^{th}source/drain region SD4, according to another embodiment. Alternatively, the backside contact structures 161 and 162 themselves may be formed by backside vias, according to another embodiment. The substrate may be formed of silicon, germanium or a combination thereof, not being limited thereto. The backside isolation structure may be formed of a dielectric material such as silicon oxide, not being limited thereto.

The cell architecture 100B may also include a 1^{st} power rail 171 and a 2^{nd} power rail 172 extended in the D1 direction at upper and lower boundaries of the cell architecture 100B, respectively. The power rails 171 and 172 may be parallel with the 1^{st} frontside metal lines M11, M15 and M16 or the backside metal lines BM1 and BM2. The power rails 171 and 172 may be formed at the same 1^{st} metal layer where the 1^{st} frontside metal lines M11, M15 and M16 are formed. The power rails 171 and 172 may be connected to the source/drain regions SD2 and SD5 formed in the active regions RX1 and RX2 through contact structures CR1 and CR2, respectively. However, the disclosure is not limited thereto. According to another embodiment, at least one of the power rails 171 and 172 may be a backside power rail formed in the substrate or the backside isolation structure, and at least one of the respective the contact structures CR1 and CR2 may be a backside contact structure, which may be formed to contact a bottom surface of the source/drain regions SD2 and/or SD5.

Additionally, the cell architecture 100B may include a plurality of vias V1, V7 and V8 connecting the frontside metal lines M11, M15, M16 and M23 to each other or the FEOL structures. The vias V2-V6 of the cell architecture 100A are replaced by the backside contact structures 161, 162 and the front-backside vias 121 and 122 in the cell architecture 100B. The front-backside vias 121 and 122 may connect the backside metal lines BM1 and BM2 to the 2^{nd} gate structure PC2. Thus, the cell architecture 100B may implement the buffer circuit with a smaller number of vias and a less complexity at the front side. Like in FIG. A, some via structures may be omitted in FIG. 1B for brevity purposes when descriptions thereof are not necessary to explain the embodiments. For similar reasons, some contact structures connecting the FEOL structures to the vias V1, V7, V8, 121, 122, the backside contact structures 161, 162 or the 1^{st} metal lines M11, M15, M16, M23, BM1 and BM2 are omitted in FIG. 1B along with descriptions thereof.

Referring to FIGS. 1B and 1C, the 1^{st} frontside metal line M11 may be connected to the 1^{st} gate structure PC1 through the via V1 therebelow to provide a common input signal V1 to the input CMOS device. The backside metal lines BM1 and BM2 may be connected to the source/drain regions SD1 and SD4 though the backside contact structures 161 and 162, respectively. These backside metal lines BM1 and BM2 may be respectively and commonly connected to the 2^{nd} gate structure PC2 through the front-back side vias 121 and 122 which may contact a top and/or side surface of the 2^{nd} gate structure PC2 and extended to be connected to the backside metal lines BM1 and BM2.

The 2^{nd} gate structure PC2 in the cell architecture 100B may be a common output node of the input CMOS device as well as a common input node of the output CMOS device. Thus, the drain terminals of the 1^{st} PMOS P1 and the 1^{st} NMOS N1 outputs respective output signals to the 2^{nd} gate structure PC2 through the backside metal lines BM1 and BM2, thereby forming an output signal Vₒᵢ of the input CMOS device at the 2^{nd} gate structure PC2. The output signal Vₒᵢ then may be input to the 2^{nd} gate structure PC2 as a common input signal of the output CMOS device formed of the PMOS P2 and the NMOS N2.

Based on the common input signal, the source/drain region SD3 of the 2^{nd} PMOS P2 and the source/drain region SD6 of the 2^{nd} NMOS N2 may output respective output signals to the 1^{st} frontside metal lines M15 and M16 though one or more contact structures and/or vias, respectively. These 1^{st} frontside metal lines M15 and M16 may be connected to the 2^{nd} frontside metal line B23 through the vias V7 and V8 thereabove, respectively, thereby to output to the 2^{nd} frontside metal line B23 the respective output signals as an output signal Vₒ of the output CMOS device, as shown in FIG. 1C.

Thus, while the cell architecture 100A shown in FIG. 1A may implement the same buffer circuit 10 using ten metal lines M11-M16, M21-M23 and M3, the cell architecture 100B shown in FIG. 1B according to the present embodiment may implement the buffer circuit 10 using only six metal lines, that is, four frontside metal lines M11, M15, M16, M23 and two backside metal lines BM1 and BM2, thereby to address complicated routing traffic at the front side of a semiconductor device formed based on the cell architecture 100A and achieve an area gain for the semiconductor device. Further, contact resistance and capacitance caused by the metal lines may be reduced in the semiconductor device. Further, as a smaller number of the frontside metal lines are formed, the process of manufacturing the semiconductor device may be facilitated.

The backside metal lines may also be formed at a back side of a three-dimensionally-stacked field-effect transistor (3DSFET) structure. The 3DSFET includes an NMOS at a lower stack and a PMOS at an upper stack (or vice versa), where each of the NMOS and PMOS may be implemented by a fin field-effect transistor (FinFET), a nanosheet transistor, or another type of transistor. The FinFET has one or more horizontally arranged vertical fin structures as a channel structure of which at least three surfaces are surrounded by a gate structure, and the nanosheet transistor is characterized by one or more nanosheet layers vertically stacked on a substrate as a channel structure, and a gate structure surrounding all four surfaces of each of the nanosheet channel layers. The nanosheet transistor is referred to as gate-all-around (GAA) transistor, multi-bridge channel field-effect transistor (MBCFET).

The embodiments described herebelow provide two cell architectures formed based on a BSPDN structure without backside metal lines and with backside metal lines.

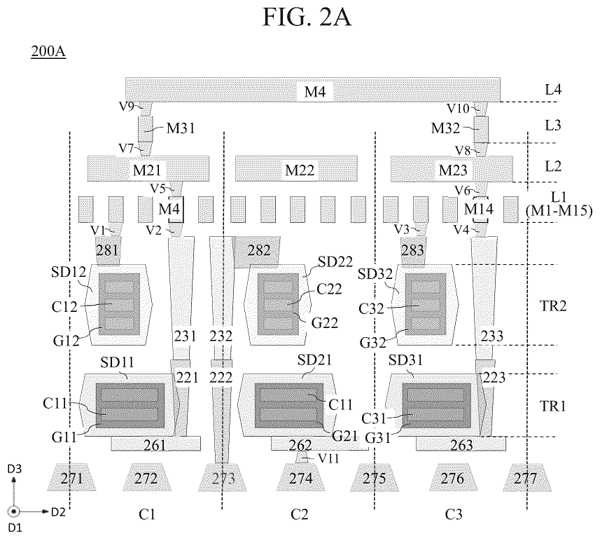

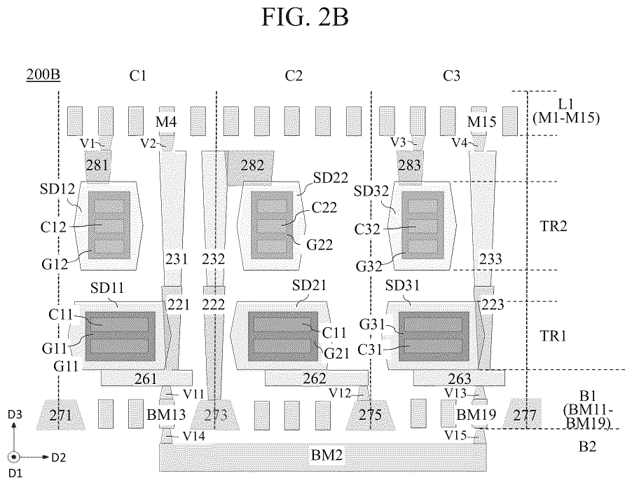

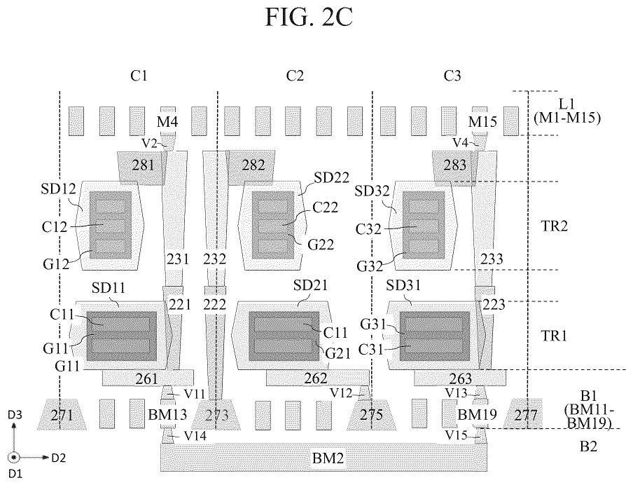

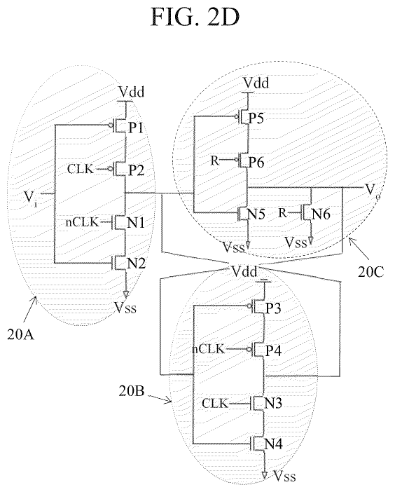

FIG. 2A is a cross-section view of a cell architecture for a latch portion of a flip-flop circuit in which a plurality of frontside metal lines and a BSPDN including a plurality of buried power rails are respectively formed above and below 3DSFETs, according to an embodiment. FIG. 2B is a cross-section view of a cell architecture for the latch portion of the flip-flop circuit in which a plurality of frontside metal lines and a BSPDN including a plurality of backside power rails and backside metal lines are respectively formed above and below 3DSFETs, according to an embodiment. FIG. 2C is a cross-section view of a cell architecture for a latch portion of a flip-flop circuit in which a plurality of frontside metal lines and a BSPDN including a plurality of backside power rails and backside metal lines are respectively formed above and below 3DSFETs, according to another embodiment. FIG. 2D is a schematic of the latch portion of the flip-flop circuit.

Referring to FIG. 2D, a latch circuit 20 which may be either a master latch or a slave latch of a flip-flop circuit may include a 1^{st} tri-state inverter 20A, a 2^{nd} tri-state inverter 20B and a NOR gate 20C which is a data path circuit of the latch circuit 20. The 1^{st} tri-state inverter 20A may be formed of two PMOSs P1, P2 and two NMOSs N1, N2 serially connected between the 1^{st} voltage source and the 2^{nd} voltage source. The 2^{nd} tri-state inverter 20B may be formed of two PMOSs P3, P4 and two NMOSs N3, N4 serially connected between the 1^{st} voltage source and the 2^{nd} voltage source. The NOR gate 20C may be formed of two PMOSs P5, P6 serially connected to each other and two NMOSs N5, N6 connected to each other in parallel. An output signal of each of the 1^{st} and 2^{nd} tri-state inverters 20A and 20B may be an input to the NOR gate 20C as an input signal thereof, and an output signal Vₒ of the NOR gate 20C, which is an output signal of the latch circuit 20, may be input to the 2^{nd} tri-state inverter 20B as an input signal thereof. When the latch circuit 20 is a master latch receiving an input signal Vᵢ from an input circuit, the output signal Vₒ of the NOR gate may be input to a slave latch, and when the latch circuit 20 is a slave latch receiving the input signal Vᵢ from a master latch, the output signal Vₒ of the NOR circuit may be input to an output inverter in the flip-flop circuit. The latch circuit 20 may also receive a clock signal CLK, an inverted clock signal nCLK, and a reset signal R at respective gates of PMOSs and NMOSs from an outside circuit to perform a latch function.

Referring to FIGS. 2A and 2D, a cell architecture 200A in which a portion of the latch circuit 20 of FIG. 2D is implemented may include 1^{st} to 3^{rd} cells C1-C3 arranged in the D2 direction, which is a channel width direction, and also a cell-height direction. The 1^{st} and 3^{rd} cells C1 and C3 may respectively implement the 1^{st} and 2^{nd} tri-state inverters 20A and 20B based on a plurality of 3DSFETs, and the 2^{nd} cell may implement the NOR gate 20C based on a plurality of 3DSFETs. It is understood here that, for drawing brevity purposes, each of the cells C1-C3 shows therein one 3DSFET implementing the respective logic circuit of the flip-flop circuit.

The 3DSFETs shown in FIG. 2A may each include a lower nanosheet transistor TR1 forming an NMOS and an upper nanosheet transistor TR2 forming a PMOS.

In the 1^{st} cell C1, the lower nanosheet transistor TR1 may include a lower source/drain region SD11 connected to one end of a lower channel structure CH11 of two nanosheet layers NC surrounded by a lower gate structure G11. Another lower source/drain region may be connected to the lower source/drain region SD11 at the other end of the lower channel structure CH11 of two nanosheet layers NC extended in the D1 direction, which is a channel-length direction and also a cell-length direction. The upper nanosheet transistor TR2 may include an upper source/drain region SD12 connected to an upper channel structure CH12 of three nanosheet layers NC surrounded by an upper gate structure G12. Another upper source/drain region may be connected to the upper source/drain region SD12 at the other end of the upper channel structure CH12 of three nanosheet layers NC extended in the D1 direction.

Similarly, the 2^{nd} cell C2 may include a lower source/drain region SD21, a lower channel structure CH21 and a lower gate structure G21 for a lower nanosheet transistor TR1, and a upper source/drain region SD22, a upper channel structure CH22 and an upper gate structure G22 for the upper nanosheet transistor TR2. Further, the 3^{rd} cell C3 may include a lower source/drain region SD31, a lower channel structure CH31 and a lower gate structure G31 for a lower nanosheet transistor TR1, and a upper source/drain region SD32, a upper channel structure CH32 and an upper gate structure G32 for the upper nanosheet transistor TR2.

The cell architecture 200A may be powered thorough a BSPDN including a plurality of backside power rails 271-277 arranged in the D2 direction and extended in the D1 direction. The backside power rails 271-277 may be alternatingly arranged to be connected to the 1^{st} voltage source and the 2^{nd} voltage source.

Further, the cells C1-C3 may include backside contact structure 261-263 formed on bottom surfaces of the lower source/drain regions of SD11, SD21 and SD31 of the respective 3DSFETs as provision for the backside power rails 271-277. When the cell architecture 200A is implemented by a semiconductor device, the backside power rails 271-277 and the backside contact structures 261-263 may be buried in a substrate or backside isolation structure. The cells C1-C3 may also include upper contact structures 281-283 formed on top surfaces of the upper source/drain regions SD12, SD22 and SD32 of the respective 3DSFETs which may connect the upper source/drain region SD12, SD22 and SD32 to other circuit elements or one or more of the backside power rails 271-277, respectively.

The cell architecture 200A may include a plurality of interconnects to implement the latch circuit 20 shown in FIG. 2D. The interconnects may include a plurality of 1^{st} frontside metal lines M1-M15, 2^{nd} frontside metal lines M21-M23, 3^{rd} frontside metal lines M31, M32 and at least one 4^{th} frontside metal line M4 at 1^{st} to 4^{th} metal layers L1-L4, respectively, stacked in this order above the 3DSFETs in the cells C1-C3. The 1^{st} metal lines M1-M15 in the 1^{st} metal layer L1 and the 3^{rd} metal lines M31, M32 may be extended in the D1 direction, while the 2^{nd} metal lines M21-M23 and the 4^{th} metal line M4 may be extended in the D2 direction. The interconnects may also include a plurality of vias V1-V10 connecting the frontside metal lines M1-M15, M21-M23, M31, M32 and M4 to each other or other circuit elements.

As described above, the 2^{nd} cell C2 may implement the NOR gate 20C of the latch circuit 20 shown in FIG. 2D. In the 2^{nd} cell C2, the upper source/drain region SD22 of the 3DSFET may implement a source terminal of the PMOS P5 of the NOR gate 20C connected to the 1^{st} voltage source (e.g., Vdd). Thus, the upper source/drain region SD22 of the 3DSFET in the 2^{nd} cell C2 may be connected to the backside power rail 273 connected to the 1^{st} voltage source. The connection of the upper source/drain region SD22 to the backside power rail 273 may be implemented by the upper contact structure 282, a side via 232 and a front-backside via 222 therebelow which are connected to each other. In contrast, the lower source/drain region SD21 of the 3DSFET in the 2^{nd} cell C2 may implement a drain terminal of the NMOS N5 of the NOR gate 20C connected to the 2^{nd} voltage source. Thus, this lower source/drain region SD21 may be connected to the backside power rail 274 connected to the 2^{nd} voltage source through the backside contact structure 262. Alternatively or additionally, a backside via V11 may be formed to connect the backside contact structure 262 to the backside power rail 274.

Further, as described above, the 1^{st} and 3^{rd} cells C1 and C3 may respectively implement the 1^{st} and 2^{nd} tri-state inverters 20A and 20B of the latch circuit 20 shown in FIG. 2D. In the 1^{st} cell C1 implementing the 1^{st} tri-state inverter 20A, the lower source/drain region SD11 of the lower nanosheet transistor TR1 may implement a drain terminal of the NMOS N1, and the upper source/drain region SD12 of the upper nanosheet transistor TR2 may implement a source terminal of the PMOS P2 connected to a drain terminal of the PMOS P1. Similarly, in the 3^{rd} cell C3, the lower source/drain region SD31 of the lower nanosheet transistor TR1 may implement a drain terminal of the NMOS N3, and the upper source/drain region SD32 of the upper nanosheet transistor TR2 may implement a source terminal of the PMOS P4 connected to a drain terminal of the PMOS P3.

In the meantime, since the drain terminal of the NMOS N1 is connected to the drain terminal of the NMOS N3 in the latch circuit 20 shown in FIG. 2D, the lower source/drain region SD11 in the 1^{st} cell C1 implementing the drain terminal of the NMOS N1 may need to be connected to the lower source/drain region SD31 in the 3^{rd} cell C3 implementing the drain terminal of the NMOS N3. To implement this connection between the two lower source/drain regions SD11 and SD31 under the above-described cell structure, a signal routing path may be formed by the backside contact structure 261, a front-backside via 221, a side via 231, the via V2, the metal line M4, the via V5, the metal line M21, the via V7, the metal line M31, the via V9, the metal line M4, the via V10, the metal line M32, the via V8, the metal line M23, the via V6, the metal line M14, the via V4, a side via 233, and a front-backside via 223.

Thus, even if the cell architecture 200A may use the BSPDN including the backside power rails 271-273 to remove power rail connection at the front side of a semiconductor device based on the cell architecture 200A, there still remains the problems of heavy signal routing traffic and a risk of connection resistance and capacitance. The following embodiments may provide improved interconnects for a cell architecture including 3DSFETs and a BSPDN to implement the same flip-flop circuit shown in FIG. 2D.

Referring to FIG. 2B, the cell architecture 200B implementing the latch circuit 20 of FIG. 2D may have the same 3DSFETs in the 1^{st} to 3^{rd} cells C1-C3 of the cell architecture 200A including the same source/drain regions, channel structures, gate structures, upper contact structures and backside contact structures, side vias, front-backside vias, first metal lines in the 1^{st} metal layer L1, and vias between the first metal lines and the upper contact structures and the first metal lines and the side vias. Thus, duplicate descriptions thereof may be omitted herebelow and only different aspects of the cell architecture 200B may be described herebelow.

The cell architecture 200B is characterized by a BSPDN including backside interconnects as well as backside power rails to implement the latch circuit 20 of FIG. 2D. As backside interconnects, the cell architecture 200B may include 1^{st} backside metal lines BM11-BM19 at a 1^{st} backside metal layer B1 and a 2^{nd} backside metal line BM2 at a 2^{nd} backside metal layer B2 below the 1^{st} backside metal layer B1. Further, the interconnects may include the backside vias V14 and V15 connecting the backside metal lines BM13 and BM19 to the 2^{nd} backside metal line BM2, respectively. In addition, backside vias V11-V13 may be provided below the backside contact structures 261-263, respectively, to connect the backside contact structures 261-263 to the 1^{st} backside metal line BM13, the backside power rail 275 and the 1^{st} backside metal line BM19, respectively. Alternatively, the backside contact structures 261-263 may directly connect the lower source/drain regions SD11-SD31 to the 1^{st} backside metal line BM13, the backside power rail 275 and the backside metal line BM19, respectively, according to another embodiment.

With the above-described BSPDN structure including the backside metal lines, the lower source/drain region SD11 (drain terminal of the NMOS N1) may be connected to the lower source/drain region SD31 (drain terminal of NMOS N3) through the backside contact structure 261, the backside via V11, the backside metal line BM13, the backside via V14, the backside metal line BM2, the backside via V15, the backside metal line BM19, the backside via V13 and the backside contact structure 263. Thus, the signal routing in the cell architecture 200B for the latch circuit 20 may be performed through the backside metal lines instead of the frontside metal lines.

However, the cell architecture 200B may still include at least the 1^{st} frontside metal lines M4 and M14 at the 1^{st} metal layer L1 as included in the cell architecture 200A, and the lower source/drain regions SD11 and SD31 may be connected to the 1^{st} frontside metal lines M4 and M15, respectively. Further, according to another embodiment, one or more of the same 1^{st} frontside metal lines M1-M15, 2^{nd} frontside metal lines M21-M23, 3^{rd} frontside metal line M31, the 4^{th} frontside metal line M4 and the via structures V5-V10 in the cell architecture 200A may be formed on the front side of the cell architecture 200B.

A semiconductor device formed based on the cell architecture 200B may be configured such that the lower source/drain regions SD11 and SD31 to implement the latch circuit 20 are connected to each other through either the frontside metal lines or the backside metal lines considering signal routing traffic at the front side and the back side of the semiconductor device. When the backside metal lines are to be used for connection of the two lower source/drain regions SD11 and SD13, at least one of the above-listed frontside interconnects may be omitted, and when the frontside metal lines are to be used for the same purpose, at least one of the backside interconnects may be omitted.

Thus, the cell architecture 200B may facilitate selective signal routing based on the interconnects formed on both the front side and the back side, thereby enabling flexible design and manufacturing of a semiconductor device implementing the latch circuit 20.

The above embodiment of the cell architecture 200B shows selective frontside or backside metal line connection between two lower source/drain regions of different cells or nets implementing different logic circuits. However, the disclosure is not limited thereto. According to other embodiments, at least one of lower and upper source/drain regions of a 3DSFET included in one cell and at least one of lower and upper source/drain regions a 3DSFET included in another cell may also be connected to each other through either a frontside metal line connection or a backside metal line connection based on the interconnects formed on both the front side and the back side of a cell architecture, as described below.

Referring to FIG. 2C, the cell architecture 200C implementing the latch circuit 20 of FIG. 2D may have the same 3DSFET structures in the 1^{st} to 3^{rd} cells C1-C3 of the cell architecture 200B including the same source/drain regions, channel structures, gate structures, upper contact structures, backside contact structures, side vias, front-backside vias, first metal lines, vias between the first metal lines and the side vias, backside power rails and backside metal lines.

However, the cell architecture 200C differs from the cell architecture 200B in that the upper source/drain regions SD12 and SD32 of the upper nanosheet transistors TR2 in the 1^{st} and 3^{rd} cells C1 and C3 may be configured to implement drain terminals of the PMOSs P2 and P4 of the latch circuit 20 shown in FIG. 2D, respectively, while the same upper source/drain regions SD12 and SD32 implement source terminals of the PMOSs P2 and P4 in the cell architecture 200B shown in FIG. 2B.

Referring to FIG. 2D, the drain terminals of the PMOSs P2 and P4 are connected to the drain terminals of the NMOSs N1 and N3, respectively, to from the respective tri-stage inverters 20A and 20B. Thus, to implement these connections, the upper source/drain regions SD12 and SD32 may be connected to the lower source/drain regions SD11 and SD31 in the 1^{st} and 3^{rd} cells C1 and C3, respectively. For example, the upper contact structures 281 and 283 may be configured to be connected to the side vias 231 and 233, respectively, so that the upper source/drain regions SD12 and SD32 are connected to the lower source/drain regions SD11 and SD32 formed therebelow in the 1^{st} and 3^{rd} cells C1 and C3, respectively.

Thus both of lower and upper source/drain regions of a 3DSFET included in one cell and both of lower and upper source/drain regions of a 3DSFET in another cell may be connected to each other through a frontside metal line connection or a backside metal line connection based on the interconnects formed on both the front side and the back side of a cell architecture.

However, the disclosure is not limited to the above embodiments. Interconnects formed on both a front side and a back side of a cell architecture may facilitate gate-to-gate connection, gate-to-source/drain region connection, passive device to an active device connection, or passive device to passive device connection through either a frontside metal line connection or a backside metal line connection whether at least one of the connected devices is a 3DSFET, a single-stack transistor or a passive device.

In the above embodiments of FIGS. 2A-2D, each of the 3DSFETs is formed of a PMOS at an upper stack and an NMOS at a lower stack. However, the disclosure is not limited thereto. The above embodiments may also apply to a 3DSFET formed of a PMOS at a lower stack and an NMOS at an upper stack.

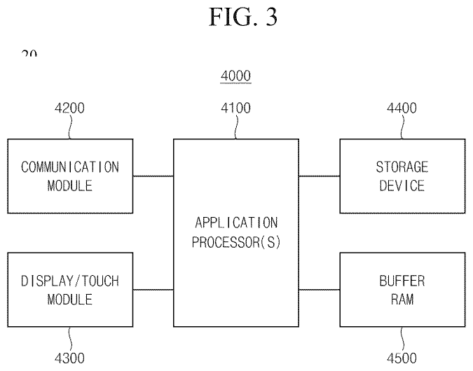

FIG. 3 is a schematic block diagram illustrating an electronic device including a semiconductor device formed based on the cell architecture 100B or 200B shown in FIGS. 1B and 2B, respectively, according to an example embodiment.

Referring to FIG. 3, an electronic device 4000 may include at least one application processor 4100, a communication module 4200, a display/touch module 4300, a storage device 4400, and a buffer random access memory (RAM) 4500. The electronic device 4000 may be a mobile device such as a smartphone or a tablet computer, not being limited thereto, according to embodiments.

The application processor 4100 may control operations of the electronic device 4000. The communication module 4200 is implemented to perform wireless or wire communications with an external device. The display/touch module 4300 is implemented to display data processed by the application processor 4100 and/or to receive data through a touch panel. The storage device 4400 is implemented to store user data. The storage device 4400 may be an embedded multimedia card (eMMC), a solid state drive (SSD), a universal flash storage (UFS) device, etc. The storage device 4400 may perform caching of the mapping data and the user data as described above.

The buffer RAM 4500 may temporarily store data used for processing operations of the electronic device 4000. For example, the buffer RAM 4500 may be volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

Although not shown in FIG. 38, the electronic device 4000 may further include at least one sensor such as an image sensor.

At least one component in the electronic device 4000 may include semiconductor device formed based on the cell architecture 100B or 200B shown in FIGS. 1B and 2B or its equivalent.

The foregoing is illustrative of example embodiments and is not to be construed as limiting the disclosure. Although some example embodiments have been described above, those skilled in the art will readily appreciate that many modifications are possible in the above embodiments without materially departing from the disclosure.

What is claimed is:

1. A semiconductor device comprising:
an input metal line at a front side of the semiconductor device; and
at least one 1^{st} output metal line at a back side of the semiconductor device,
wherein the input metal line is configured to receive an input signal of a 1^{st} logic circuit, and
wherein the 1^{st} output metal line is configured to output an output signal of the 1^{st} logic circuit.

2. The semiconductor device of claim 1, wherein the 1^{st} logic circuit comprises a 1^{st} inverter circuit comprising a 1^{st} p-type field-effect transistor (FET) and a 1^{st} n-type FET.

3. The semiconductor device of claim 2, further comprising:
an input contact structure or via at the back side of the semiconductor device; and
at least one 2^{nd} output metal line at the front side of the semiconductor device,
wherein the input contact structure or via is configured to receive the output signal of the 1^{st} logic circuit as an input signal of a 2^{nd} logic circuit, and
wherein the 2^{nd} output metal line is configured to output an output signal of the 2^{nd} logic circuit.

4. The semiconductor device of claim 3, wherein the input contact structure or via is extended to the front side of the semiconductor device.

5. The semiconductor device of claim 4, wherein the 2^{nd} logic circuit comprises a 2^{nd} inverter comprising a 2^{nd} p-type FET and a 2^{nd} n-type FET.

6. The semiconductor device of claim 1, further comprising:
an input contact structure or via at the back side of the semiconductor device; and
at least one 2^{nd} output metal line at the front side of the semiconductor device,
wherein the input contact structure or via is configured to receive the output signal of the 1^{st} logic circuit as an input signal of a 2^{nd} logic circuit, and
wherein the 2^{nd} output metal line is configured to output an output signal of the 2^{nd} logic circuit.

7. The semiconductor device of claim 1, further comprising:
a 1^{st} gate structure connected to the input metal line to receive the input signal of the 1^{st} logic circuit;
a 1^{st} source/drain region; and
a 2^{nd} source/drain region,
wherein the at least one 1^{st} output metal line comprises:
a 1^{st} backside metal line connected to the 1^{st} source/drain region; and
a 2^{nd} backside metal line connected to the 2^{nd} source/drain region.

8. The semiconductor device of claim 7, further comprising
an input contact structure or via at the back side of the semiconductor device;
a 2^{nd} gate structure connected to the input contact structure or via to receive the output signal of the 1^{st} logic circuit as an input signal of a 2^{nd} logic circuit;
a 3^{rd} source/drain region;
a 4^{th} source/drain region; and
at least one 2^{nd} output metal line at the front side of the semiconductor device,
wherein the 2^{nd} output metal line is connected to at least one of the 3^{rd} and 4^{th} source/drain regions to receive and output an output signal of the 2^{nd} logic circuit.

9. A semiconductor device comprising:
a 1^{st} frontside metal line at a front side of the semiconductor device; and
a 1^{st} backside metal line at a back side of the semiconductor device,
wherein the 1^{st} backside metal line is connected to the 1^{st} frontside metal line.

10. The semiconductor device of claim 9, further comprising a 1^{st} front-end-of-line (FEOL) structure comprising at least one of a 1^{st} source/drain region and a 1^{st} gate structure, and connected to the 1^{st} frontside metal line and the 1^{st} backside metal line.

11. The semiconductor device of claim 10, wherein the 1^{st} source/drain region and the 1^{st} gate structure forms either a lower field-effect transistor or an upper field-effect transistor stacked on the lower field-effect transistor.

12. The semiconductor device of claim 9, further comprising a 1^{st} front-end-of-line (FEOL) structure comprising:
at least one of a 1^{st} lower source/drain region and a 1^{st} lower gate structure; and
at least one of a 1^{st} upper source/drain region and a 1^{st} upper gate structure stacked above the 1^{st} lower source/drain region and the 1^{st} lower gate structure, respectively, wherein the at least one of the 1^{st} lower source/drain region and the 1^{st} lower gate structure is connected to the at least one of the 1^{st} upper source/drain region and the 1^{st} upper gate structure, respectively.

13. The semiconductor device of claim 9, further comprising:
a 2^{nd} frontside metal line at the front side of the semiconductor device; and
a 2^{nd} backside metal line at the back side of the semiconductor device,
wherein the 2^{nd} backside metal line is connected to the 2^{nd} frontside metal line, and
wherein the 1^{st} frontside metal line and the 1^{st} backside metal line correspond to a 1^{st} semiconductor cell, and the 2^{nd} frontside metal line and the 2^{nd} backside metal line correspond to a 2^{nd} semiconductor cell.

14. The semiconductor device of claim 13, wherein one of a connection between the 1^{st} and 2^{nd} frontside metal lines and a connection between the 1^{st} and 2^{nd} backside metal lines is configured to be selectively enabled.

15. The semiconductor device of claim 14, further comprising at least one backside power rail.

16. The semiconductor device of claim 13, further comprising a 2^{nd} front-end-of-line (FEOL) structure comprising at least one of a 2^{nd} source/drain region and a 2^{nd} gate structure, and connected to the 2^{nd} frontside metal line and the 2^{nd} backside metal line.

17. The semiconductor device of claim 16, wherein the 2^{nd} source/drain region and the 2^{nd} gate structure forms either a lower field-effect transistor or an upper field-effect transistor stacked on the lower field-effect transistor.

18. The semiconductor device of claim 16, further comprising a 1^{st} FEOL structure comprising at least one of a 1^{st} source/drain region and a 1^{st} gate structure, and connected to the 1^{st} frontside metal line and the 1^{st} backside metal line, and
wherein the 1^{st} and 2^{nd} FEOL structures are connected to each other through the 1^{st} and 2^{nd} backside metal lines or through the 1^{st} and 2^{nd} frontside metal lines.

19. The semiconductor device of claim 18,
wherein the 1^{st} FEOL structure comprises:
at least one of a 1^{st} lower source/drain region and a 1^{st} lower gate structure; and
at least one of a 1^{st} upper source/drain region and a 1^{st} upper gate structure stacked above the 1^{st} lower source/drain region and the 1^{st} lower gate structure, respectively,
wherein the at least one of the 1^{st} lower source/drain region and the 1^{st} lower gate structure is connected to the at least one of the 1^{st} upper source/drain region and the 1^{st} upper gate structure, respectively,
wherein the 2^{nd} FEOL structure comprises:
at least one of a 2^{nd} lower source/drain region and a 2^{nd} lower gate structure; and
at least one of a 2^{nd} upper source/drain region and a 2^{nd} upper gate structure stacked above the 2^{nd} lower source/drain region and the 2^{nd} lower gate structure, respectively, and
wherein the at least one of the 2^{nd} lower source/drain region and the 2^{nd} lower gate structure is connected to the at least one of the 2^{nd} upper source/drain region and the 2^{nd} upper gate structure, respectively.

20. The semiconductor device of claim 19, wherein one of a connection between the 1^{st} and 2^{nd} frontside metal lines and a connection between the 1^{st} and 2^{nd} backside metal lines is configured to be selectively enabled.

21. A semiconductor device comprising:
a 1^{st} front-end-of-line (FEOL) structure comprising at least one of a 1^{st} source/drain region and a 1^{st} gate structure;
a 1^{st} frontside metal line; and
a 1^{st} backside metal line,
wherein the 1^{st} FEOL structure is configured to be selectively connected to one of the 1^{st} frontside metal line and the 1^{st} backside metal line.

22. The semiconductor device of claim 21, further comprising:
a 2^{nd} FEOL structure comprising at least one of a 2^{nd} source/drain region and a 2^{nd} gate structure;
a 2^{nd} frontside metal line; and
a 2^{nd} backside metal line,
wherein the 2^{nd} FEOL structure is selectively connected to one of the 2^{nd} frontside metal line and a 2^{nd} backside metal line, and
wherein the 1^{st} frontside metal line and the 1^{st} backside metal line correspond to a 1^{st} semiconductor cell, and the 2^{nd} frontside metal line and the 2^{nd} backside metal line correspond to a 2^{nd} semiconductor cell.

23. The semiconductor device of claim 21, wherein one of a connection between the 1^{st} and 2^{nd} frontside metal lines and a connection between the 1^{st} and 2^{nd} backside metal lines is configured to be selectively enabled.
